(19) United States
(12) Patent Application Publication
(10) Pub. No.: US 2005/0196707 A1
(43) Pub. Date: Sep. 8, 2005

(54) Patterned conductive coatings

(75) Inventor: Ronald S. Cok, Rochester, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 10/791,116

(22) Filed: Mar. 2, 2004

(51) Int. Cl. G03F 7/00

(52) U.S. Cl. 430/318; 430/313; 430/321

(57) ABSTRACT

A method of continuously manufacturing a patterned conductive layer includes the steps of providing a linearly moving substrate; coating a dispersion containing conductive nano-materials onto a surface of the linearly moving substrate; drying the coated dispersion wherein the nano-materials self-align into a conductive layer; coating a protective layer of radiation-curable material over the nano-materials coated on the linearly moving substrate; exposing the protective layer coating to patterned radiation and curing the exposed pattern in the protective layer; and removing uncured sections of the protective layer and the underlying sections of the conductive layer to form a patterned conductive layer.

### FIELD OF THE INVENTION

The present invention relates to a method for manufacturing patterned conductive coatings and more particularly to the use of nano-materials in such coatings.

### BACKGROUND OF THE INVENTION

Flat-panel displays rely upon patterned transparent conductive materials deposited on a substrate to provide power to the light emitting or light controlling elements that provide a pixilated display. Such coatings are conventionally made of indium tin oxide (ITO) and are patterned using conventional photolithographic techniques including the deposition of photo-resist, exposing the photo-resist to radiation through a mask, and washing the resulting patterned coating. The coatings of ITO are typically deposited by sputtering at a high temperature. However, such processes are slow and expensive and are not readily employed in continuous manufacturing processes.

Alternative means for providing transparent conductive coatings are known. For example, tiny particles of wires or carbon nano-tubes are known, having at least one dimension 100 nm or less, more typically 10 nm or less. For example, WO2002076724 A1 entitled “Coatings Containing Carbon Nano-tubes” published 20021003 discloses electrically conductive films containing nano-tubes. The disclosed films demonstrate excellent conductivity and transparency. Methods of preparing and using the films are disclosed. Such films are suggested for use in, for example conductive surfaces such as are found in touch screens. However, these films are not patterned in a way that makes them useful for applications requiring patterned conductors, for example in flat-panel displays or touch screens.

In an alternative use of nano-material conductors, WO2003016209A1 entitled “Nano-scale Electronic Devices & Fabrication Methods” by Brown et al, published 20030227 describes a method of forming a conducting nano-wire between two contacts on a substrate surface wherein a plurality of nano-particles is deposited on the substrate in the region between the contacts, and the single nano-wire running substantially between the two contacts is formed by either by monitoring the conduction between the contacts and ceasing deposition at the onset of conduction, and/or modifying the substrate to achieve, or taking advantage of pre-existing topographical features which will cause the nano-particles to form the nano-wire. The resultant conducting nano-wires are also claimed as well as devices incorporating such nano-wires. However, such an approach is slow and it is difficult to form conductors over large areas.

Other nano-materials and deposition methods are described, for example, in U.S. Pat. No. 6,294,401B1 entitled “Nanoparticle-based electrical, chemical, and mechanical structures and methods of making same” by Jacobson et al and issued 20010925 which describes the use of printing technologies for the deposition and patterning of nano-materials. However, such techniques the use of specific carrier matrix materials or do not provide protection for fragile nano-material depositions. The deposition methods disclosed may also inhibit self-alignment of nano-materials on a surface.

US20030189202A1 entitled “Nano-wire devices and methods of fabrication” by Li, et al and Published 20031009 describes nano-wire devices based on carbon nano-tubes or single- crystal semiconductor nano-wires. The nano-wire devices may be formed on a silicon substrate or other suitable substrate. Electrodes may be patterned on the substrate. A material such as an insulator may be formed on the nano-wires following nano-wire growth. The insulator may be planarized using chemical-mechanical polishing or other suitable techniques. The resulting nano-wire device may be used in chemical or biological sensors, as a field emitter for displays, or for other applications. However, these methods are not readily employed in continuous manufacturing processes.

There is a need therefore for an improved method of patterning transparent conductive coatings in a low-cost and efficient process.

### SUMMARY OF THE INVENTION

The need is met by a method of continuously manufacturing a patterned conductive layer that includes the steps of providing a linearly moving substrate; coating a dispersion containing conductive nano-materials onto a surface of the linearly moving substrate; drying the coated dispersion wherein the nano-materials self-align into a conductive layer; coating a protective layer of radiation-curable material over the nano-materials coated on the linearly moving substrate; exposing the protective layer coating to patterned radiation and curing the exposed pattern in the protective layer; and removing uncured sections of the protective layer and the underlying sections of the conductive layer to form a patterned conductive layer.

### ADVANTAGES

The present invention has the advantage of providing an improved method for manufacturing a patterned nano-material conductor.

### BRIEF DESCRIPTION OF THE DRAWINGS

FIG. 1 is a schematic cross sectional view of a patterned conductive coating made according to the method of the present invention;

FIG. 2 is a flow diagram of one embodiment of the present invention;

FIG. 3 is a schematic diagram of the manufacturing method of an embodiment of the present invention;

FIGS. 4a-d are schematic cross-sectional views of a substrate and conductive coating at various stages of manufacture according to one embodiment of the method of the present invention;

FIG. 5 is a schematic cross sectional view of an alternative embodiment of a patterned conductive coating made according to the method of the present invention; and

FIG. 6 is a schematic cross sectional view of multi-layered patterned conductive coatings made according to one embodiment of the method of the present invention.

### DETAILED DESCRIPTION OF THE INVENTION

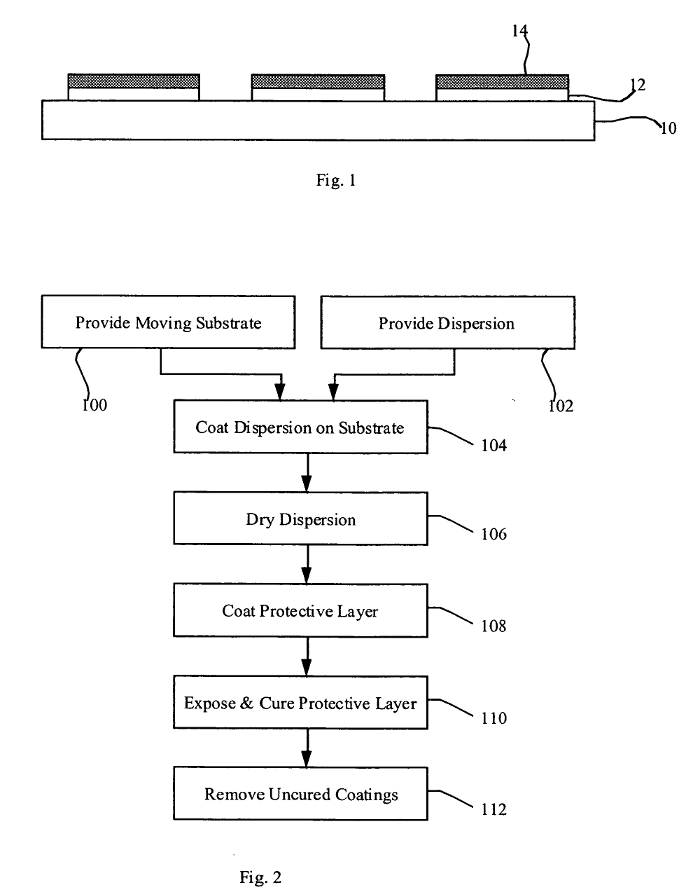

Referring to FIG. 1, the present invention is directed to a method for manufacturing a patterned conductive coating 12 formed on a substrate 10. The patterned conductor includes a layer of nano-materials, for example, carbon nano-tube conductors or nano-wires, covered by a patterned polymeric resin binder protective layer 14 to hold the nano-materials in place and to protect them from physical trauma. The polymeric resin binder is cured through exposure to radiation and may be transparent or colored using pigments or dyes to provide light absorbing properties. The colors can be, for example, red, green, blue, cyan, magenta, yellow or black. Carbon black may be used to provide a black colorant that will absorb all colors of light.

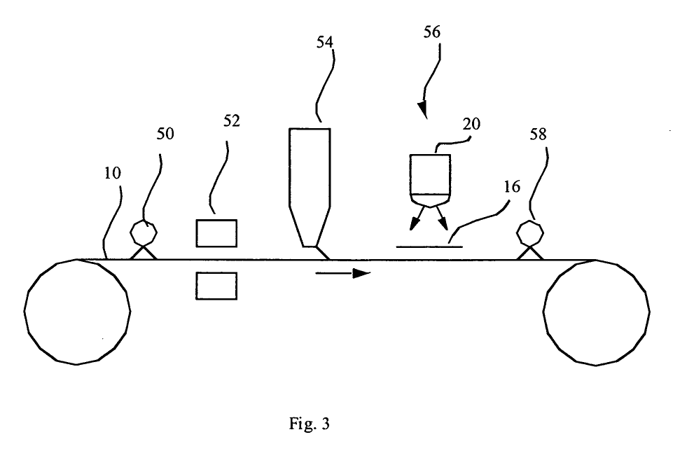

Referring to FIG. 2, the method of the present invention for continuously manufacturing a patterned conductive layer comprises the steps of providing 100 a linearly moving substrate; providing 102 a dispersion containing conductive nano-materials; coating 104 the dispersion onto a surface of the linearly moving substrate; drying 106 the coated dispersion wherein the nano-materials self-align into a conductive layer; coating 108 a protective layer of radiation-curable material over the nano-materials coated on the linearly moving substrate; exposing 110 the protective layer coating to patterned radiation and curing the exposed pattern in the protective layer; and removing 112 uncured sections of the protective layer and the underlying sections of the conductive layer to form a patterned conductive layer.

For the purposes of the invention, nano-materials are defined as materials having at least one dimension of less than or equal to 100 nm, preferably less than or equal to 10 nm. The construction of conductive nano-materials, including nanotubes, preparation of coatable dispersions, and their deposition are all known in the art. See, for example, WO2002076724 A1 and U.S. Pat. No. 6,294,401B1 cited above. Preferably, the nano-materials are provided in aqueous dispersion form; alternatively, other solvents may be used.

Referring to FIG. 3, one embodiment of the method of the present invention is illustrated. A continuously moving substrate 10 in the form of a web is provided. The web has a width, for example one meter, but an indefinite length and moves continuously in a linear fashion in the direction of the indefinite length. In the depicted embodiment, the web is the substrate itself, and may be flexible. In another alternative (not shown), the substrate 10 may be discontinuous portions of rigid material, for example glass, positioned on a continuously moving belt. At a coating station 50, a dispersion containing conductive nano-materials is coated onto the surface of the linearly moving substrate. A drying station 52 dries the dispersion at a rate and in a manner such that the nano-materials self-align into a conductive, preferably transparent layer. A protective coating station 54 coats a protective layer of radiation-curable material over the nano-materials coated on the linearly moving substrate 10. An exposing station 56 exposes the protective layer to patterned radiation. This can be accomplished using a radiation source 20 (for example an ultraviolet light source) and a mechanical mask 16 having a pattern. The curing of the protective layer may be enhanced through the application of heat. Once the section of the exposed protective layer is cured, the uncured sections of the protective layer and the underlying sections of the conductive layer are removed, for example with a washing station 58, to form a patterned conductive layer.

Because the substrate 10 is continuously moving, exposure through a stationary mask must be done in a relatively short time with respect to the distance traveled by the substrate during that time. Alternatively, the mask may be moved together with the substrate, thereby enabling longer exposure times. The radiation source 20 may also move with the mask 16 or may provide radiation over an area to provide consistent radiation through the mask to the protective layer during the exposure time.

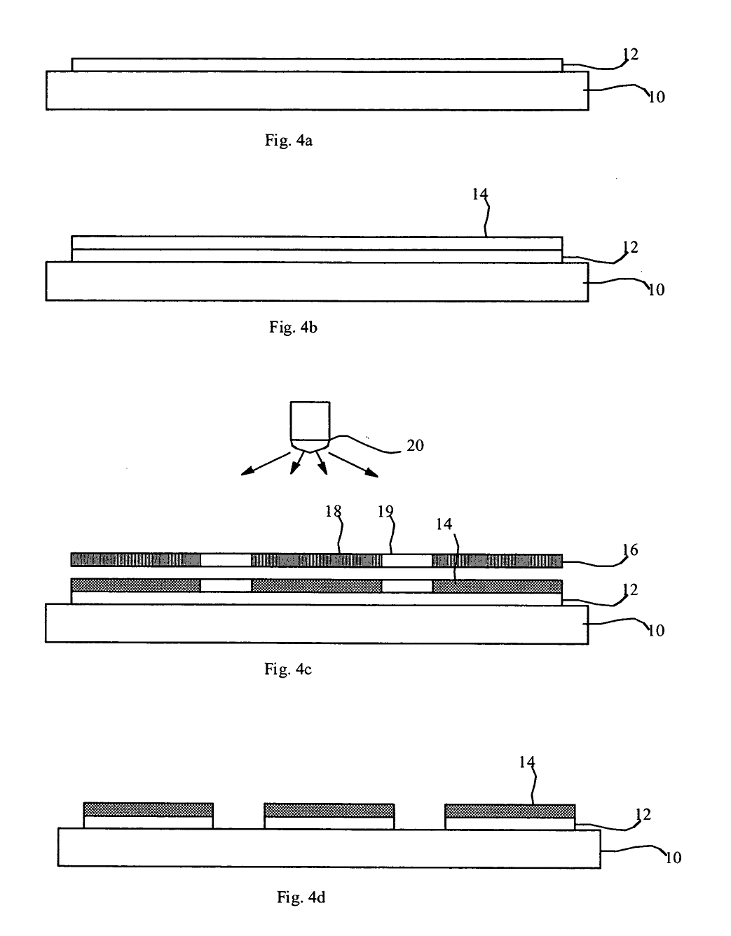

The method of the present invention is illustrated graphically in FIGS. 4a-d. Referring to FIG. 4a, in a first step a substrate 10 has a coating of a nano-materials dispersion deposited on it to form conductive, preferably transparent, unpatterned conductive layer 12. Referring to FIG. 4b, in a second step a radiation-curable material, for example a UV-curable polymer, is coated over the conductive layer 12 to form an unpatterned protective layer 14. Referring to FIG. 4c, the radiation-curable material is then exposed from a radiation source 20 through mask 16 having a light-transmissive portion 18 and non-light-transmissive portion 19 to cure the exposed portions of the radiation-curable material underneath the transmissive portion 18 of the mask 16. Once the radiation-curable material is cured in a pattern, the non-cured radiation-curable material and any underlying conductive nano-material is removed, typically by washing, leaving a patterned, preferably light-transparent, conductive nano-material behind, see FIG. 4d.

The present invention employs unpatterned coating and washing methods compatible with low-cost, continuous manufacturing techniques and equipment. Such coating methods can include, for example, spray coating, curtain coating, and slot coating. Unpatterned methods are especially useful over large surface areas with low-cost equipment in which coated nano-materials can self-align and be protected in a continuous process.

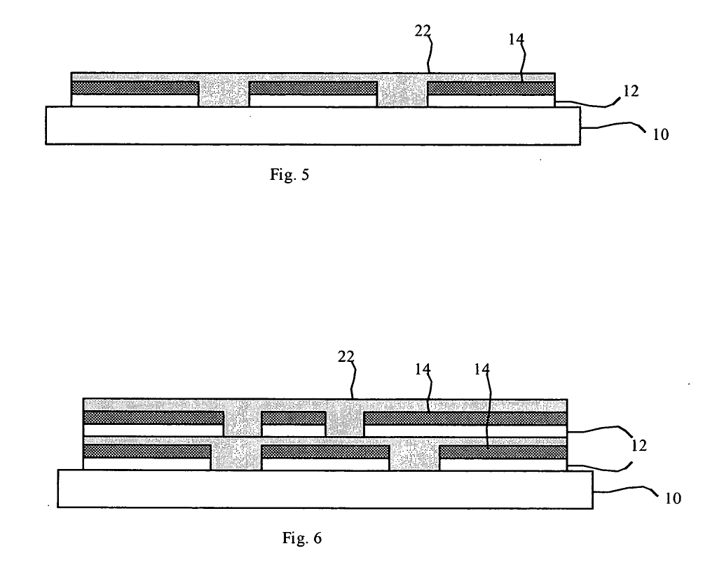

Several layers of dried, dispersed nano-materials may be applied before the protective layer is applied to improve the conductivity or other attributes of the conductors. The method of the present invention may be extended to form a planarization layer 22 of protective material over the patterned conductive layer, as shown in FIG. 5. In another embodiment of the present invention, conductive and protective coatings may be applied iteratively to create multiple layers of conductors separated by insulating layers of protective materials, as shown in FIG. 6. Voids may also be left in different layers to provide conductivity between portions of different conductive layers.

Suitable radiation-cured polymers are known in the art, for example, US20030138733A1 entitled “UV-Curable Compositions And Method Of Use Thereof In Microelectronics” by Sachdev et al describes a radiation-curable composition for use in the fabrication of electronic components as passivation coatings; for defect repair in ceramic and thin film products by micropassivation in high circuit density electronic modules to allow product recovery; as a solder mask in electronic assembly processes; for use as protective coatings on printed circuit board (PCB) circuitry and electronic devices against mechanical damage and corrosion from exposure to the environment. The compositions are solvent-free, radiation-curable, preferably uv-curable, contain a polymer binder, which is a pre-formed thermoplastic or elastomeric polymer/oligomer, a monofunctional and/or bifunctional acrylic monomer, a multifunctional (more than 2 reactive groups) acrylated/methacrylated monomer, and a photoinitiator, where all the constituents are mutually miscible forming a homogeneous viscous blend without the addition of an organic solvent. The compositions may also contain inorganic fillers and/or nanoparticle fillers. Patternable colored polymeric resins or polymers having dyes or pigments are also known, and may be used where it is desired to provide a colored protective layer, e.g., to provide light filtering capability. Alternative materials, such as photo-resists, may also be used.

The method of the present invention may be employed to pattern conductors on a substrate, for example substrates used in flat-panel displays such as LCD or OLED displays or in touch screens. If a continuous flexible substrate is employed, the substrate may be cut after the final washing step. Alternatively, after processing the substrate may be rolled in a continuous web.

While the use of conductive nanomaterials advantageously enables the continuous production of light-transparent patterned conductors in accordance with the invention, the patterned conductive coating 12 may also be reflective or absorptive, depending on the nature of the materials. For example, sufficiently dense layers of carbon nano-tubes become opaque and absorptive. Additional materials may be added to the nano-materials after coating and before or after drying to affect the local properties of the nano-material, for example to affect the conductivity, reflectivity, color, or flexibility of the conductive layer.

The present invention can be employed in most OLED device configurations, such as passive-matrix displays having orthogonal arrays of anodes and cathodes to form pixels, and active-matrix displays where each pixel is controlled independently, for example, with a thin film transistor (TFT). As is well known in the art, OLED devices and light emitting layers include multiple organic layers, including hole and electron transporting and injecting layers, and emissive layers. Such configurations are included within this invention.

The present invention may also be employed in touch screen devices requiring conductive coatings, for example in resistive touch screen having coated substrates or flexible top sheets. In particular, the present invention may be employed to pattern coatings on flexible top sheets and, with reference to the description used here, the flexible top sheets may be considered substrates for the purposes of this invention.

The invention has been described in detail with particular reference to certain preferred embodiments thereof, but it will be understood that variations and modifications can be effected within the spirit and scope of the invention.

### PARTS LIST

10 substrate

12 conductive coating

14 protective layer

16 mask

18 radiation-transmissive portion

19 non-radiation-transmissive portion

20 radiation source

22 planarizing layer

50 coating station

52 drying station

54 coating station

56 exposing station

58 washing station

100 provide moving substrate step

102 provide dispersion step

104 coat dispersion step

106 dry dispersion step

108 coat protective layer step

110 expose protective layer step

112 remove step

1. A method of continuously manufacturing a patterned conductive layer comprising the steps of:
a) providing a linearly moving substrate;
b) coating a dispersion containing conductive nano-materials onto a surface of the linearly moving substrate;
c) drying the coated dispersion wherein the nano-materials self-align into a conductive layer;
d) coating a protective layer of radiation-curable material over the nano-materials coated on the linearly moving substrate;
e) exposing the protective layer coating to patterned radiation and curing the exposed pattern in the protective layer; and
f) removing uncured sections of the protective layer and the underlying sections of the conductive layer to form a patterned conductive layer.

2. The method claimed in claim 1, wherein the conductive nano-materials are nano-wires.

3. The method claimed in claim 1, wherein the conductive nano-materials are carbon nano-tubes.

4. The method claimed in claim 1, wherein the radiation-curable material is a polymer.

5. The method claimed in claim 1, wherein the radiation-curable material is a photo-resist.

6. The method claimed in claim 1, wherein the radiation is ultra-violet radiation.

7. The method claimed in claim 1, wherein the substrate is a flat-panel display substrate.

8. The method claimed in claim 1, wherein the substrate is a touchscreen substrate.

9. The method claimed in claim 1, further comprising coating and drying a plurality of nano-material coatings before the protective layer is coated.

10. The method claimed in claim 1, further comprising coating a second protective layer over the patterned protective layer to planarize the surface.

11. The method claimed in claim 10, further comprising coating and patterning a second nano-material conductive layer on the planarized surface.

12. The method claimed in claim 1, further comprising coating and patterning a second nano-material conductive layer on the patterned conductive layer.

13. The method claimed in claim 1, wherein the patterned conductive layer is transparent.

14. The method claimed in claim 1, wherein the patterned conductive layer is opaque.

15. The method claimed in claim 1, wherein the patterned conductive layer is reflective.

16. The method claimed in claim 1, wherein the nano-materials are sprayed, slot or curtain coated.

17. The method claimed in claim 1, wherein the substrate is a continuous flexible substrate.

18. The method claimed in claim 1, wherein the substrate is a discontinuous substrate provided on a continuous moving belt.

19. The method claimed in claim 1, wherein the protective layer is exposed to patterned radiation through a mask.

20. The method claimed in claim 19, wherein the source of radiation is stationary.

21. The method claimed in claim 20, wherein the mask is stationary.

22. The method claimed in claim 19, wherein the mask and substrate move together during exposure.

23. The method claimed in claim 22, wherein the mask, source of radiation and substrate move together during exposure.

24. The method claimed in claim 1, wherein the protective layer is colored.

25. The method claimed in claim 1, wherein the protective layer is light-transparent.

26. A patterned conductor comprising a patterned nano-material conductive layer and a correspondingly patterned protective layer thereon.

27. The patterned conductor claimed in claim 26, wherein the patterned protective layer comprises ultra-violet radiation absorptive material.

28. The patterned conductor claimed in claim 26, wherein the patterned protective layer comprises cured polymeric resin binder.

29. The patterned conductor claimed in claim 26, wherein the patterned protective layer is transparent.

30. The patterned conductor claimed in claim 26, wherein the patterned protective layer is colored.
